(19) United States
(12) Patent Application Publication
(10) Pub. No.: US 2007/0084407 A1
(43) Pub. Date: Apr. 19, 2007

(54) Apparatus and method for manufacturing carbon nanotubes

(75) Inventor: Chi-Chuang Ho, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/439,921

(22) Filed: May 24, 2006

(30) Foreign Application Priority Data
Oct. 14, 2005 (TW) 200510100354.4

(51) Int. Cl. C23C 16/00

(52) U.S. Cl. 118/724

(57) ABSTRACT

An apparatus for manufacturing carbon nanotubes is provided. The apparatus includes a reaction chamber, a substrate supporter, a guiding means, a first electrode, a second electrode, and a power supply. The reaction chamber has an inlet and an outlet. The reaction chamber receives the substrate supporter, the guiding means, the first electrode, and the second electrode. The substrate supporter intercepts across a gas flow of the carbon-containing gas and substantially perpendicular with a path of the gas flow. The first electrode and the second electrode are disposed opposite to each other for creating an electrical field in the reaction chamber. A part of the electrical field perpendicularly penetrates the substrate supporter to control the carbon nanotubes growing in an aligning manner according to a direction of the electrical field. The first electrode and the second electrode each has a plurality of through holes allowing the carbon-containing gas to flow therethrough.

### BACKGROUND

1. TECHNICAL FIELD

The present invention relates to carbon nanotubes, and more particularly to an apparatus and method for manufacturing carbon nanotubes by chemical vapor deposition (CVD).

2. DISCUSSION OF RELATED ART

Generally, it has been known that carbon nanotubes can be manufactured by methods including plasma discharge, laser ablation, and CVD using a carbon-containing gas.

CVD is a method of growing carbon nanotubes by a chemical decomposition reaction of the carbon-containing gas, using acetylene gas, methane gas, or the like containing carbon as a raw material. The chemical vapor deposition depends on a chemical reaction occurring in the carbon-source gas as part of a thermal decomposition process, thereby enabling the manufacture of high-purity carbon nanotubes.

Conventional apparatuses for growing carbon nanotubes usually have carbon-containing gas sweeping horizontally over substrates, on which carbon nanotubes are growing, in order to deliver carbon atoms for the growing nanotubes. However, carbon nanotubes formed by such apparatuses have shortcomings. During the manufacturing process, the direction of the gas flow is substantially parallel with a catalyst layer, while the nanotubes grow upwardly perpendicular to the catalyst layer. As such, although rather slow, the horizontal movement of the gas flow disturbs the growing process of the nanotubes and alters the vertical alignment of the carbon nanotubes.

Therefore, what is needed in the art is to provide an apparatus for manufacturing vertically aligned carbon nanotubes.

### SUMMARY

In one aspect of the present invention, an apparatus for manufacturing carbon nanotubes is provided. The apparatus includes a reaction chamber, a substrate supporter, a guiding means, a first electrode, a second electrode, and a power supply.

The reaction chamber has an inlet and an outlet. The inlet is configured for introducing a carbon-containing gas thereinto. The outlet is configured for allowing the carbon-containing gas evacuating therefrom. The reaction chamber receives the substrate supporter, the guiding means, the first electrode, and the second electrode therein. The substrate supporter is configured for supporting a substrate for growing carbon nanotubes thereon. The substrate supporter intercepts across a gas flow of the carbon-containing gas and substantially perpendicular with a path of the gas flow. The first electrode and the second electrode are disposed opposite to each other for creating an electrical field in the reaction chamber. A part of the electrical field perpendicularly penetrates the substrate supporter so as to control the carbon nanotubes growing in an aligning manner according to a direction of the electrical field distributed therearound. The first electrode and the second electrode each has a plurality of through holes allowing the carbon-containing gas to flow therethrough.

Detailed features of the present carbon nanotubes manufacturing apparatus will become more apparent from the following detailed description and claims, and the accompanying drawings.

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views, wherein:

FIG. 1 is a schematic cross-sectional view of an apparatus for manufacturing carbon nanotubes according to an exemplary embodiment;

FIG. 2 is a schematic top view of an electrode (either the first or the second) for the apparatus for manufacturing carbon nanotubes as shown in FIG. 1;

FIG. 3 is a schematic side view of a first electrode and a second electrode with an electrical field associated therewith schematically illustrated, according to an aspect of the embodiment as shown in FIG. 1; and

FIG. 4 is a schematic side view of a first electrode and a second electrode with an electrical field associated therewith schematically illustrated, according to another aspect of the embodiment as shown in FIG. 1.

### DETAILED DESCRIPTION OF PREFERRED EMBODIMENTS

Reference will now be made to the drawings to describe the preferred embodiments of the present apparatus for manufacturing carbon nanotubes, in detail.

Referring now particularly to FIG. 1, an apparatus 100 for manufacturing carbon nanotubes according to a first embodiment is shown. The apparatus 100 mainly includes a reaction chamber 110, a substrate supporter 120, a first electrode 140, a second electrode 150, and a power supply 160.

The reaction chamber 110 receives the substrate supporter 120, the first electrode 140 and the second electrode 150 therein. The reaction chamber 110 has an inlet 112 and an outlet 114. The inlet 112 is configured for introducing a carbon-containing gas into the reaction chamber 110, thus providing carbon atoms for growing the carbon nanotubes (not shown), and the outlet 114 is configured for allowing the carbon-containing gas evacuating therefrom. The carbon-containing gas flows from the inlet 112 to the outlet 114 along a path 116. The power supply 160 is electrically connected with the first electrode 140 and the second electrode 150 for supplying a voltage therebetween when growing carbon nanotubes.

According to an aspect of the embodiment, the apparatus 100 further includes a guiding means 130. The guiding means 130 is received in the reaction chamber 110, cooperative with the inlet 112 and the outlet 114, defining the path 116 along which the gas flow is guided to move.

The substrate supporter 120 is configured for supporting a substrate (not shown) having a catalyst layer (not shown) configured thereupon for upwardly growing carbon nanotubes thereon. The substrate supporter 120 is disposed across the path 116 of the gas flow and allows the gas to flow thereby.

According to another aspect of the embodiment, the substrate supporter 120 is a grid plate configured across the path. The substrate supporter 120 has a plurality of through holes (not shown), cooperatively configured in accordance with the path 116, allowing the gas flow to flow therethrough.

According to another embodiment of the present apparatus, a plurality of substrate supporters 120 are disposed across the path 116. The substrate supporters are parallel with and spaced from each other. As such, more substrates having catalyst disposed thereupon are allowed to be set in the reaction chamber 110 for growing more carbon nanotubes.

The first electrode 140 and the second electrode 150 are disposed opposite to each other. When a voltage is applied between the first electrode 140 and the second electrode 150, an electrical field occurs thereby. A part of the electrical field substantially perpendicularly penetrates the substrate supporter 120. Therefore, when the carbon nanotubes grow upon the substrate on the substrate supporter 120, a growing direction thereof is controlled in an aligning manner according to a direction of the electrical field distributed therearound.

The first electrode 140 and the second electrode 150 are configured for applying an electrical field onto the substrate supporter 120. To obtain aligned carbon nanotubes grown, a direction of the electrical field is preferred to be consistent with the growing direction of the carbon nanotubes.

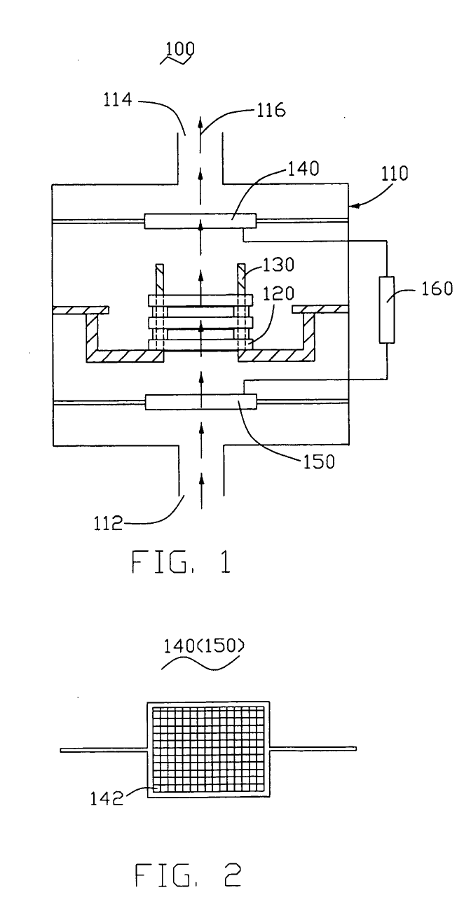

When areas of the first electrode 140 and the second electrode 150 are much greater than an area of the substrate supporter 120, and the first electrode 140 and the second electrode 150 are relatively close to each other, the electrical filed applied on each of the substrates are approximately perpendicular to the substrate and consistent with the growing direction of the carbon nanotubes. Referring to FIG. 2, there is shown a top view of the first electrode 140 and the second electrode 150 under the foregoing condition. According to this embodiment, the first electrode 140 and the second electrode 150 have equivalent shape and size, and are mirroring to each other. The first electrode 140 and the second electrode 150 are grid-shaped electrodes including a plurality through holes 142 configured for allowing the gas flow to pass therethrough without being disturbed.

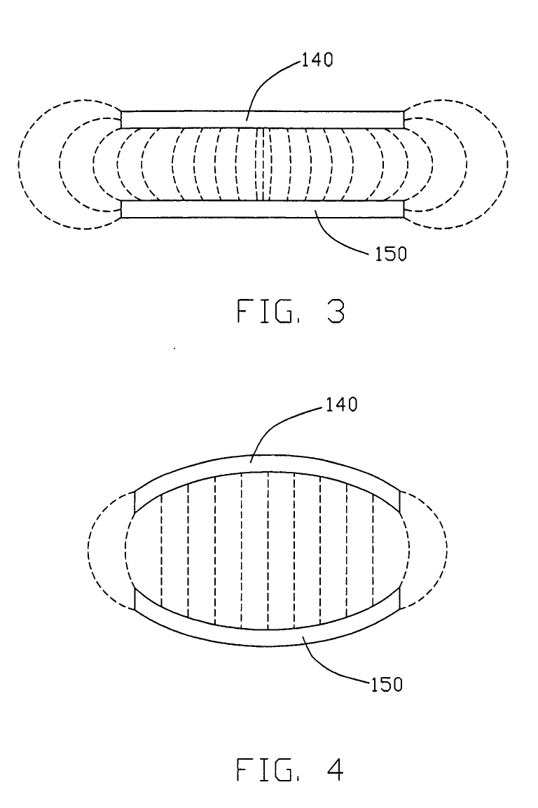

It is to be noted that, although a planar electrode pair create a substantially straight electrical field in a space corresponding to their central areas, in a peripheral space corresponding to their peripheries, the electrical field is curved outwardly as shown in FIG. 3. When the first electrode 140 and the second electrode 150 are designed to have areas comparative to that of the substrate supporter 120, for the purpose of, for example making the apparatus more compact, the first electrode 140 and the second electrode 150 can be configured to have other forms.

According to another embodiment of the apparatus 100, the first electrode 140 and the second electrode 150 have the same top view as shown in FIG. 2 and disposed in positions as shown in FIG. 1. However, referring to FIG. 4, the first electrode 140 and the second electrode 150 are convexly shaped and oppositely disposed to each other, in that a distance between respective center parts thereof are greater than a distances between respective peripheral parts thereof. As such, a more uniform electrical field spatial distribution can be obtained.

Furthermore, according to an aspect of the embodiment, the second electrode 150 itself can function as a substrate supporter. In such a way, the substrate supporters 120 are optional and not necessarily needed.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. An apparatus for manufacturing carbon nanotubes, the apparatus comprising:
a reaction chamber having an inlet configured for introducing a carbon-containing gas thereinto, and an outlet configured for allowing the carbon-containing gas evacuating therefrom, the carbon-containing gas moving and configuring as a gas flow in the chamber from the inlet to the outlet, the carbon-containing gas flowing from the inlet to the outlet along a path thereby;
a substrate supporter for supporting a substrate configured for growing carbon nanotubes thereon, the substrate supporter intercepting across the gas flow and substantially perpendicular with the path of the gas flow therearound; and
a first electrode and a second electrode disposed opposite to each other, for creating an electrical field in the reaction chamber, a part of the electrical field being perpendicularly penetrating the substrate supporter, so as to control the carbon nanotubes growing in accordance with a direction of the electrical field distributed therearound,
wherein the first electrode and the second electrode each has at least one through hole allowing the carbon-containing gas to flow therethrough.

2. The apparatus according to claim 1 further comprising a power supply for providing a voltage level difference between the first electrode and the second electrode.

3. The apparatus according to claim 1, wherein at least one of the first electrode and the second electrode is a grid-shaped electrode, configured for allowing the gas flow to pass therethrough without being disturbed.

4. The apparatus according to claim 1, wherein the first electrode and the second electrode have equivalent shape and size, and are mirroring to each other.

5. The apparatus according to claim 1, wherein at least one of the first electrode and the second electrode is planar shaped.

6. The apparatus according to claim 1, wherein at least one of the first electrode and the second electrode is convexly shaped.

7. The apparatus according to claim 1, wherein the substrate supporter is a grid plate configured across the path for supporting the substrate, wherein the grid plate has a plurality of through holes allowing the gas flow to flow therethrough.

8. An apparatus for manufacturing carbon nanotubes, the apparatus comprising:
a reaction chamber having an inlet configured for introducing a carbon-containing gas thereinto, and an outlet configured for allowing the carbon-containing gas evacuating therefrom, the carbon-containing gas configuring a gas flow in the chamber from the inlet to the outlet;
a guiding means disposed in the reaction chamber, defining a path, along which the gas flow is guided to move;
a substrate supporter configured for supporting a substrate for growing carbon nanotubes thereon, the substrate being disposed across the path of the flow and allowing the gas to flow thereby; and
a first electrode and a second electrode disposed opposite to each other, for creating an electrical field in the reaction chamber, a part of the electrical field being perpendicularly penetrating the substrate supporter, so as to control the carbon nanotubes growing in an aligning manner according to a direction of the electrical field distributed therearound,
wherein the first electrode and the second electrode each has at least one through hole allowing the gas to flow therethrough.

9. An apparatus for manufacturing carbon nanotubes, the apparatus comprising:
a reaction chamber having an inlet configured for introducing a carbon-containing gas thereinto, and an outlet configured for allowing the carbon-containing gas evacuating therefrom, the carbon-containing gas configuring a gas flow in the chamber from the inlet to the outlet;
a guiding means disposed in the reaction chamber, defining a path, along which the gas flow is guided to flow, wherein the gas flow moving substantially positively or adversely along a direction of the nanotubes growth, when passing by the substrate;
a first grid electrode having a plurality of through holes allowing the gas to flow therethrough; and
a second grid electrode, also functioning as a substrate supporter configured for supporting a substrate for growing carbon nanotubes thereon, the substrate being disposed across the path of the gas flow and allowing the gas to flow thereby, the grid electrode and the substrate supporter being disposed opposite to each other, for cooperatively creating an electrical field in the reaction chamber when applied with a voltage level difference therebetween, a part of the electrical field being perpendicularly penetrating the substrate supporter, so as to control the carbon nanotubes growing in an aligning manner and consistent with a direction of the electrical field distributed therearound.

10. The apparatus according to claim 9 further comprising one or more supplemental substrate supporters disposed over and spaced from the substrate supporter, the supplemental supporters being spaced one from another and having through holes for allowing the gas flow flowing there through.
